(19) United States
(12) Patent Application Publication
(10) Pub. No.: US 2021/0225832 A1
(43) Pub. Date: Jul. 22, 2021

(54) TRANSIENT-VOLTAGE-SUPPRESSION DIODE STRUCTURE AND MANUFACTURING METHOD THEREOF

(71) Applicant: Mosel Vitelic Inc., Hsinchu (TW)

(72) Inventors: Chi-Neng Chou, Hsinchu (TW); Hsiu-Fang Lo, Hsinchu (TW); Yung-An Sun, Hsinchu (TW)

(21) Appl. No.: 16/918,460

(22) Filed: Jul. 1, 2020

(30) Foreign Application Priority Data
Jan. 17, 2020 (TW) 109101629

(51) Int. Cl. H01L 27/02; H01L 29/861; H01L 29/66

(52) U.S. Cl. CPC H01L 27/0248; H01L 29/66098; H01L 29/861

(57) ABSTRACT

A transient-voltage-suppression diode structure and a manufacturing method thereof are disclosed. The structure includes a P type base substrate, an N type epitaxial layer, a P+ type implant layer, an N+ type implant layer, a plurality of deep trench portions, an interlayer dielectric layer and a first metal layer. The N type epitaxial layer is disposed on the P type base substrate. The P+ type implant layer and the N+ type implant layer are embedded within the N type epitaxial layer. The deep trench portions pass through the N type epitaxial layer and are connected with the P type base substrate. The first metal layer is disposed on the interlayer dielectric layer and connected with the P+ type implant layer, the N+ type implant layer, and the deep trench portions. The deep trench portions connected with the first metal layer are configured to form a silicon controlled rectifier.

### FIELD OF THE INVENTION

The present disclosure relates to a diode structure, and more particularly to a transient-voltage-suppression diode structure and a manufacturing method thereof.

### BACKGROUND OF THE INVENTION

A transient-voltage-suppression diode, also called as a TVS diode, is an electronic device used to protect electronics from voltage spikes induced on connected wires. In recent years, as the development of electronic systems has become more sophisticated, the demand for TVS device has become more and more urgent.

A conventional TVS device can be combined with a silicon controlled rectifier (SCR). FIG. 1 is a cross sectional view illustrating a conventional TVS diode structure combined with a silicon controlled rectifier. In the embodiment, the TVS device 1 includes a bottom metal layer 18, a P type base layer 10, an N type buried layer 21, an N type epitaxial layer 11, a P+ type implant layer 13, an N+ type implant layer 14, an interlayer dielectric (ILD) layer 15, a top metal layer 16 and a passivation layer 17. The P+ type implant layer 13 and the N+ type implant layer 14 are embedded in the N type epitaxial layer 11. The top metal layer 16 is connected with the P+ type implant layer 13 and the N+ type implant layer 14 by passing through the interlayer dielectric layer 15. The TVS device 1 further includes a plurality of isolation trench portions 12 configured to isolate the P+ type implant layer 13 and the N+ type implant layer 14. The N type buried layer 21 is disposed between the P type base layer 10 and the N type epitaxial layer 11, and spatially corresponds to the P+ type implant layer 13. In addition, the TVS device 1 further includes a silicon controlled rectifier 20. Notably, in the conventional TVS device 1, the silicon controlled rectifier 20 is produced by forming the P+ type implant layer 13, the N+ type implant layer 14 and the interlayer dielectric layer 15 and then forming a recess 19 through the wet etching procedure. After the forming procedures of the top metal layer 16 and the passivation layer 17 are completed, the silicon controlled rectifier 20 is formed and located in the recess 19. However, since the wet etching procedure is utilized to produce the silicon controlled rectifier 20, the etching rate is not easy to control, and the metal is not easy to be filled within. It results that the stability of producing the TVS device 1 is not good.

Therefore, there is a need of providing a transient-voltage-suppression diode structure and a manufacturing method thereof to address the above issues encountered by the prior arts.

### SUMMARY OF THE INVENTION

An object of the present disclosure is to provide a transient-voltage-suppression diode structure and a manufacturing method thereof. The structure of a plurality of deep trench portions formed by for example the dry etching are introduced, it is helpful to avoid the problems of the instability of manufacturing process, the difficulty of controlling the etching rate, and the poor metal filling, which are caused by the wet etching. The performance of the transient-voltage-suppression diode structure is further improved. In addition, the structure of the deep trench portions is utilized to construct a silicon controlled rectifier, it is helpful to control the size thereof and provide the better electrical connection characteristics. While the plurality of deep trench portions are formed by a doped polycrystalline silicon material, the structure of the plurality of deep trench portions is further helpful to reduce the parasitic resistance of, for example the N type epitaxial layer, so as to improve the performance of the transient-voltage-suppression diode structure.

Another object of the present disclosure is to provide a transient-voltage-suppression diode structure and a manufacturing method thereof. A plurality of polycrystalline deep trench portions formed by for example the dry etching are utilized to construct the silicon controlled rectifier, and it benefits to eliminate the instability of manufacturing process caused by the wet etching and reduce the complexity of manufacturing process. In addition, the structure of silicon controlled rectifier constructed by the plurality of deep trench portions is helpful to control the size thereof and the better electrical connection characteristics of the silicon controlled rectifier are provided. While the plurality of deep trench portions are formed by a doped polycrystalline silicon material, the problem of poor metal filling is avoided, and the parasitic resistance of, for example the N type epitaxial layer is further reduced, so that the performance of the transient-voltage-suppression diode structure is improved.

In accordance with an aspect of the present disclosure, a transient-voltage-suppression diode structure is provided and includes a P type base substrate, an N type epitaxial layer, at least one P+ type implant layer, at least one N+ type implant layer, a plurality of deep trench portions, an interlayer dielectric layer and a first metal layer. The P type base substrate includes a first side and a second side. The first side and the second side are opposite to each other. The N type epitaxial layer is disposed on the first side of the P type base substrate. The at least one P+ type implant layer is embedded within the N type epitaxial layer. The at least one N+ type implant layer is embedded within the N type epitaxial layer, and isolated from the at least one P+ type implant layer. The plurality of deep trench portions pass through the N type epitaxial layer. Each of the plurality of deep trench portions has a first end and a second end opposite to each other, and the first ends are connected with the P type base substrate. The interlayer dielectric layer is disposed on the N type epitaxial layer. The at least one P+ type implant layer, the at least one N+ type implant layer, and the second ends of the plurality of deep trench portions are exposed from the interlayer dielectric layer. The first metal layer is disposed on the interlayer dielectric layer and connected with the at least one P+ type implant layer, the at least one N+ type implant layer, and the second ends of the plurality of deep trench portions. The plurality of deep trench portions connected with the first metal layer are configured to form a silicon controlled rectifier.

In an embodiment, the plurality of deep trench portions include a doped polycrystalline silicon layer.

In an embodiment, the plurality of deep trench portions are formed by a dry etching procedure.

In an embodiment, the transient-voltage-suppression diode structure further includes an N type buried layer. The N type buried layer spatially corresponds to the at least one P+ type implant layer and is disposed between the P type base substrate and the N type epitaxial layer.

In an embodiment, the transient-voltage-suppression diode structure further includes a passivation layer. The passivation layer is disposed on the first metal layer, and the first metal layer is partially exposed from the passivation layer.

In an embodiment, the transient-voltage-suppression diode structure further includes a second metal layer disposed on the second side of the P type base substrate.

In an embodiment, the transient-voltage-suppression diode structure further includes a plurality of isolation trench portions passing through the N type epitaxial layer and partially extended to the P type base substrate. The plurality of isolation trench portions are located among the at least one P+ type implant layer, the at least one N+ type implant layer and the plurality of deep trench portions, to isolate the at least one P+ type implant layer, the at least one N+ type implant layer and the plurality of deep trench portions from each other.

In an embodiment, each of the plurality of isolation trench portions includes an oxide layer and a polycrystalline silicon layer, and the oxide layer covers an outer periphery and a bottom of the polycrystalline silicon layer.

In accordance with another aspect of the present disclosure, a manufacturing method of a transient-voltage-suppression diode structure is provided and incudes steps of: (a) providing a P type base substrate including a first side and a second side, wherein the first side and the second side are opposite to each other; (b) forming at least one N type epitaxial layer disposed on the first side of the P type base substrate; (c) partially etching the N type epitaxial layer to form a plurality of deep trenches passing through the N type epitaxial layer; (d) filling the plurality of deep trenches with a polycrystalline silicon material to form a plurality of deep trench portions, wherein each of the plurality of deep trench portions has a first end and a second end opposite to each other, and the first ends are connected with the P type base substrate; (e) forming at least one P+ type implant layer and at least one N+ type implant layer embedded in the N type epitaxial layer respectively, wherein the at least one P+ type implant layer, the at least one N+ type implant layer are isolated from each other; (f) forming an interlayer dielectric layer disposed on the N type epitaxial layer, wherein the at least one P+ type implant layer, the at least one N+ type implant layer, and each of the second ends of the plurality of deep trench portions are exposed from the interlayer dielectric layer; and (g) forming a first metal layer disposed on the interlayer dielectric layer, wherein the first metal layer is connected with the at least one P+ type implant layer, the at least one N+ type implant layer, and the second ends of the plurality of deep trench portions, wherein the plurality of the deep trench portions connected with the first metal layer are configured to form a silicon controlled rectifier.

In an embodiment, the polycrystalline silicon material is a doped polycrystalline silicon material, and the plurality of deep trench portions comprise a doped polycrystalline silicon layer.

In an embodiment, the plurality of deep trenches in the step (c) are formed by a dry etching procedure.

In an embodiment, the step (b) further includes a step of: (b0) forming an N type buried layer, wherein the N type buried layer is disposed between the P type base substrate and the N type epitaxial layer, and spatially corresponds to the at least one P+ type implant layer.

In an embodiment, the method further includes a step of: (h1) forming a passivation layer disposed on the first metal layer and partially exposing the first metal layer.

In an embodiment, the method further includes a step of: (h2) forming a second metal layer disposed on the second side of the P type base substrate.

In an embodiment, the step (c) further includes a step of: (c0) forming a plurality of isolation trench portions passing through the N type epitaxial layer and partially extended to the P type base substrate, wherein the plurality of isolation trench portions are located among the at least one P+ type implant layer, the at least one N+ type implant layer and the plurality of deep trench portions, to isolate the at least one P+ type implant layer, the at least one N+ type implant layer and the plurality of deep trench portions from each other.

In an embodiment, the step (c0) further includes steps of: (c01) partially etching the at least one N type epitaxial layer and the P type base substrate to form a plurality of isolation trenches passing through the N type epitaxial layer; (c02) forming an oxide layer disposed on lateral walls and bottoms of the plurality of isolation trenches; and (c03) filling the plurality of isolation trenches with a polycrystalline silicon material to form a plurality of isolation trench portions, wherein the plurality of isolation trench portions pass through the N type epitaxial layer and are partially extended to the P type base substrate, wherein the plurality of isolation trench portions are located among the at least one P+ type implant layer, the at least one N+ type implant layer and the plurality of deep trench portions, to isolate the at least one P+ type implant layer, the at least one N+ type implant layer and the plurality of deep trench portions from each other.

The above contents of the present disclosure will become more readily apparent to those ordinarily skilled in the art after reviewing the following detailed description and accompanying drawings, in which:

### BRIEF DESCRIPTION OF THE DRAWINGS

FIG. 1 is a cross sectional view illustrating a conventional TVS diode structure;

FIG. 2 is a cross sectional view illustrating a transient-voltage-suppression diode structure according to an embodiment of the present disclosure;

FIGS. 3A to 3K are cross sectional views illustrating the transient-voltage-suppression diode structure at several manufacturing stages according to the embodiment of the present disclosure; and

FIGS. 4A and 4B are a flow chart showing a manufacturing method of a transient-voltage-suppression diode structure according to an embodiment of the present disclosure.

### DETAILED DESCRIPTION OF THE PREFERRED EMBODIMENT

The present disclosure will now be described more specifically with reference to the following embodiments. It should be noted that the following descriptions of preferred embodiments of this disclosure are presented herein for purpose of illustration and description only. It is not intended to be exhaustive or to be limited to the precise form disclosed.

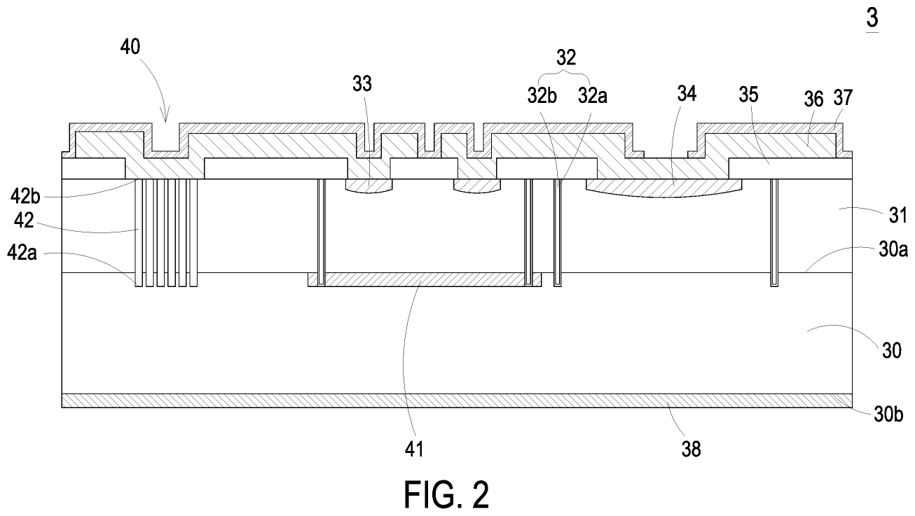

FIG. 2 is a cross sectional view illustrating a transient-voltage-suppression diode structure according to an embodiment of the present disclosure. In the embodiment, the transient-voltage-suppression diode structure 3 includes a P type base substrate 30, an N type epitaxial layer 31, a plurality of isolation trench portion 32, at least one P+ type implant layer 33, at least one N+ type implant layer 34, a plurality of deep trench portions 42, an interlayer dielectric layer 35, a first metal layer 36, a passivation layer 37 and a second metal layer 38. The P type base substrate 30 includes a first side 30a and a second side 30b. The first side 30a and the second side 30b are opposite to each other. The N type epitaxial layer 31 is disposed on the first side 30a of the P type base substrate 30. The at least one P+ type implant layer 33 is embedded within the N type epitaxial layer 31. The at least one N+ type implant layer 34 is embedded within the N type epitaxial layer 31. Preferably but not exclusively, the at least one N+ type implant layer 34 and the at least one P+ type implant layer 33 are isolated from each other through the plurality of isolation trench portions 32. Moreover, in the embodiment, the plurality of deep trench portions 42 pass through the N type epitaxial layer 31. Each of the plurality of deep trench portions 42 has a first end 42a and a second end 42b opposite to each other. In the embodiment, the first ends 42a are connected with and extended to the P type base substrate 30. In addition, the interlayer dielectric layer 35 is disposed on the N type epitaxial layer 31. Preferably but not exclusively, the at least one P+ type implant layer 33, the at least one N+ type implant layer 34, and the second ends 42b of the plurality of deep trench portions 42 are exposed from the interlayer dielectric layer 35. The first metal layer 36 is disposed on the interlayer dielectric layer 35 and connected with the at least one P+ type implant layer 33, the at least one N+ type implant layer 34 and the second ends 42b of the plurality of deep trench portions 42. The plurality of deep trench portions 42 connected with the first metal layer 36 are configured to form a silicon controlled rectifier 40.

In the embodiment, the transient-voltage-suppression diode structure 3 further includes a passivation layer 37 disposed on the first metal layer 36 and partially exposing the first metal layer 36 to define an output terminal. In addition, the transient-voltage-suppression diode structure 3 further includes a second metal layer 38 disposed on the second side 30b of the P type base substrate 30. In the embodiment, the transient-voltage-suppression diode structure 3 further includes an N type buried layer 41. The N type buried layer 41 spatially corresponds to the at least one P+ type implant layer 33 and is disposed between the P type base substrate 30 and the N type epitaxial layer 31. Certainly, the present disclosure is not limited thereto.

Notably, the plurality of deep trench portions 42 are formed by for example but not limited to the dry etching procedure. Preferably but not exclusively, the plurality of deep trench portions 42 are filled with a doped polycrystalline silicon layer. Since the plurality of deep trench portions 42 are produced by for example the dry etching merely, it benefits to eliminate the instability of manufacturing process caused by the wet etching and reduce the complexity of manufacturing process. In addition, the structure of silicon controlled rectifier 40 constructed by the plurality of deep trench portions 42 is helpful to control the size thereof and the better electrical connection characteristics of the silicon controlled rectifier are provided. Furthermore, the plurality of deep trench portions 42 are formed by a doped polycrystalline silicon material, it benefits to avoid the problem of poor metal filling, and the parasitic resistance of, for example the N type epitaxial layer 31 is further reduced, so that the performance of the transient-voltage-suppression diode structure 3 is improved.

In the embodiment, the plurality of isolation trench portions 32 are located among for example but not limited to the at least one P+ type implant layer 33, the at least one N+ type implant layer 34 and the plurality of deep trench portions 42, so as to isolate the at least one P+ type implant layer 33, the at least one N+ type implant layer 34 and the plurality of deep trench portions 42 from each other. Preferably but not exclusively, each of the plurality of isolation trench portions 32 includes an oxide layer 32a and a polycrystalline silicon layer 32b, and the oxide layer 32a covers an outer periphery and a bottom of the polycrystalline silicon layer 32b. However, it is not an essential feature to limit the present disclosure, and not redundantly described herein.

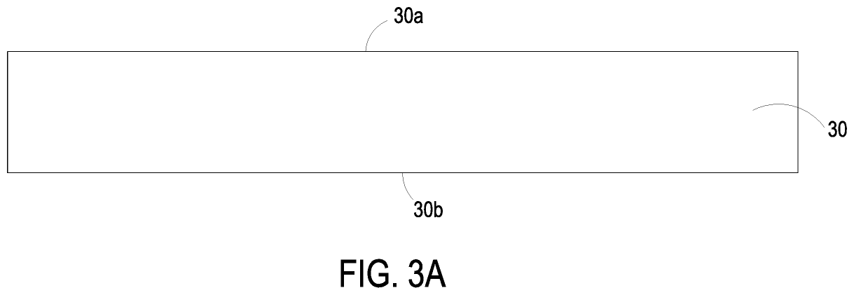

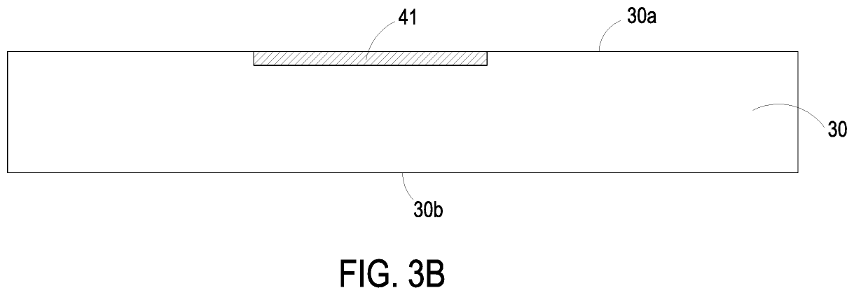

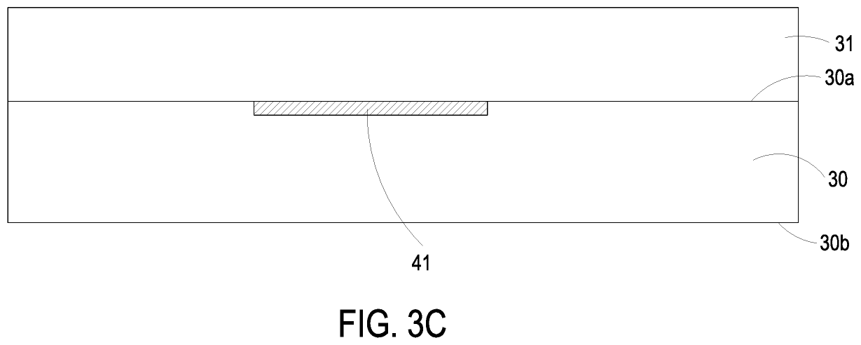

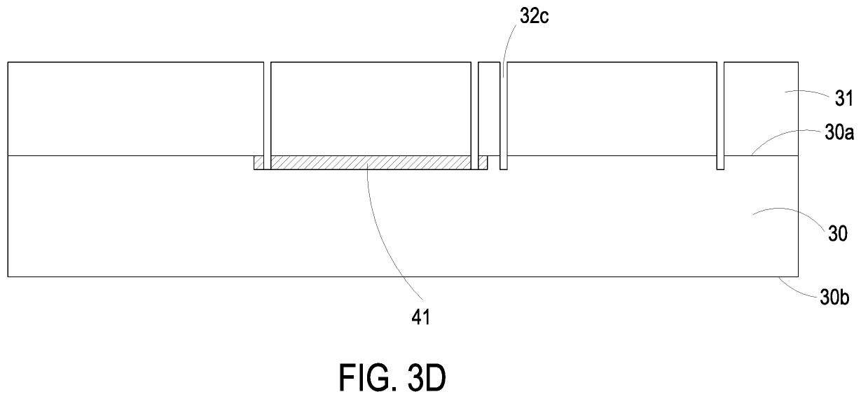

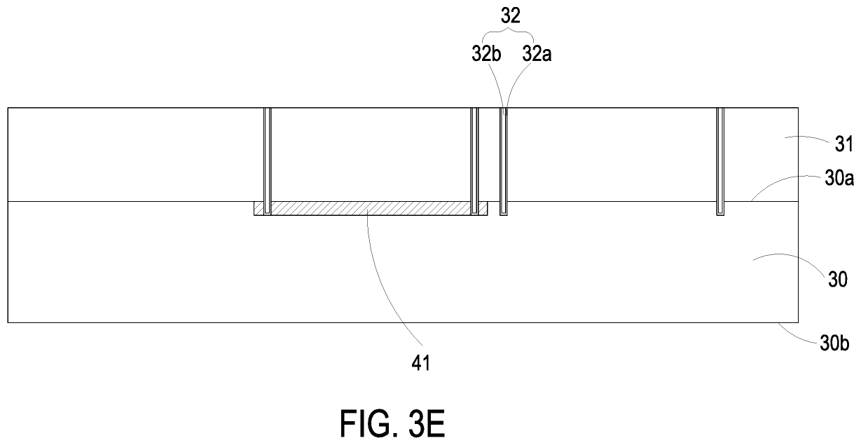

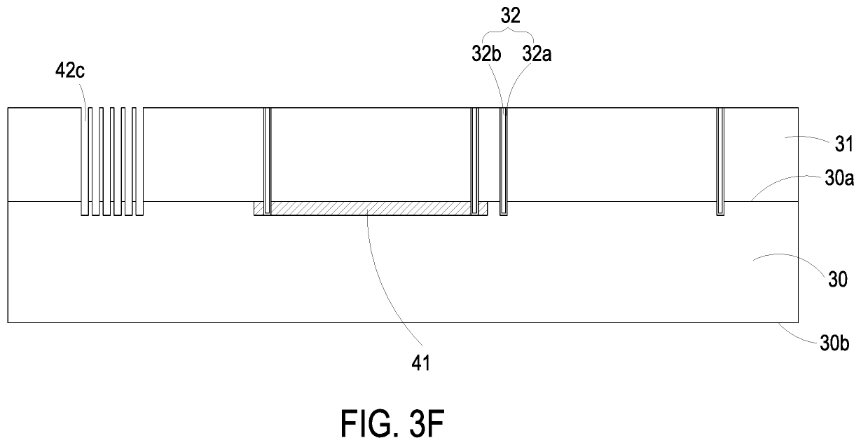

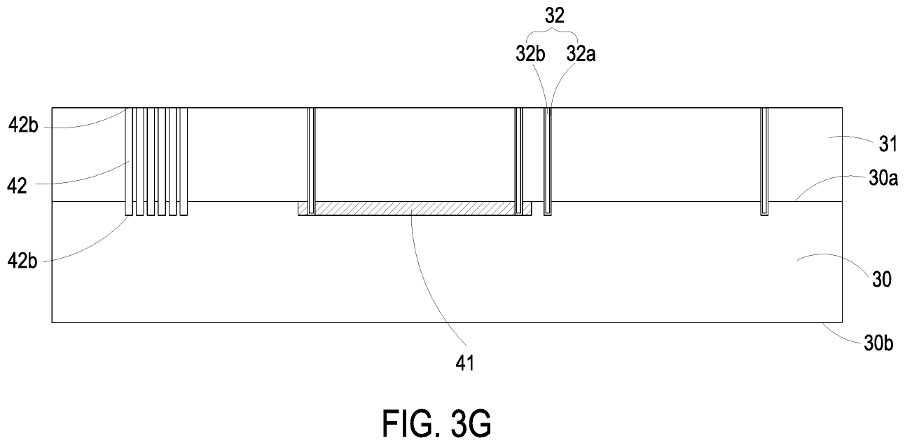

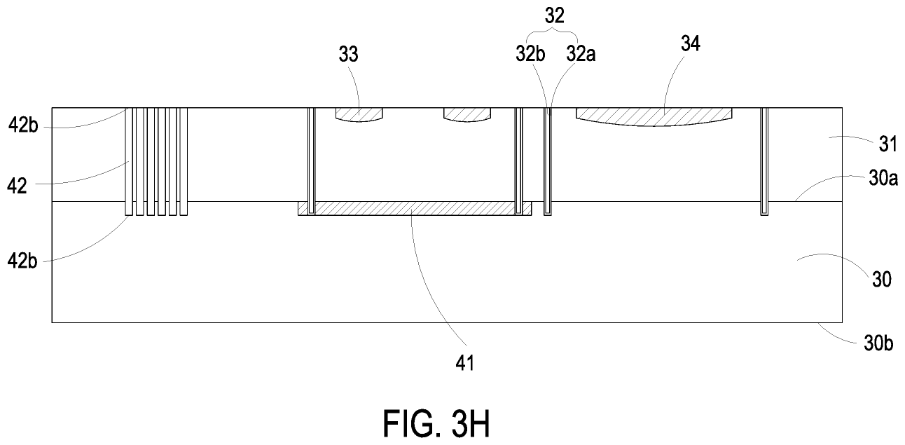

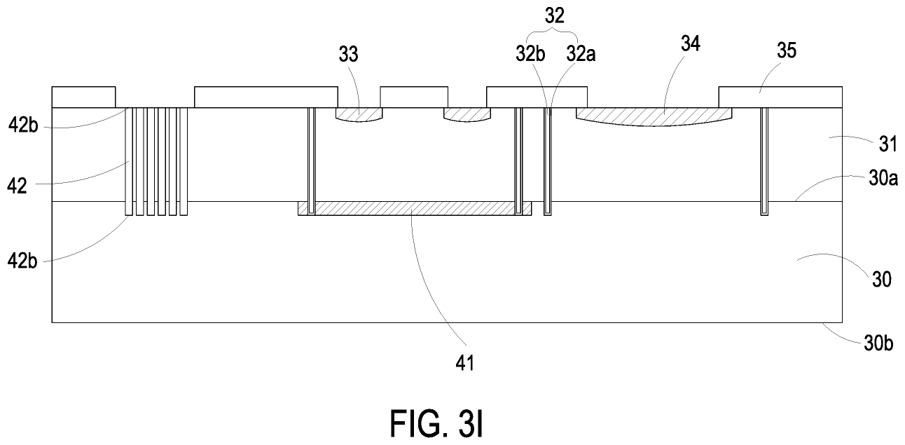

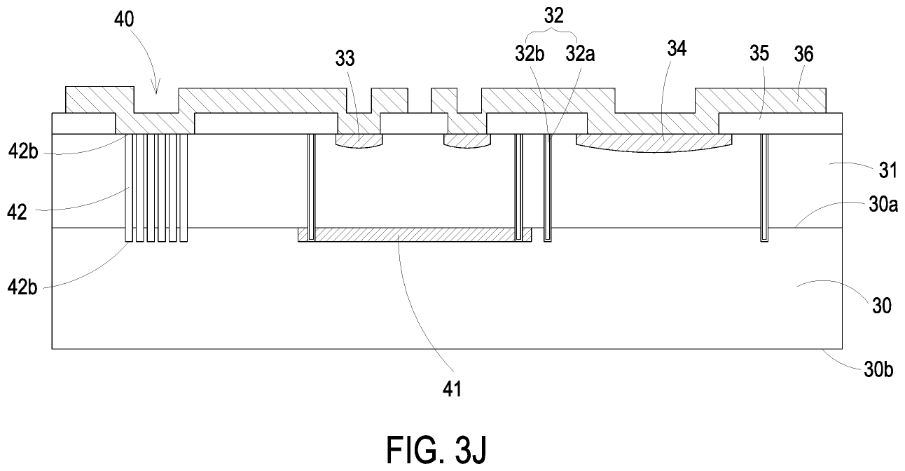

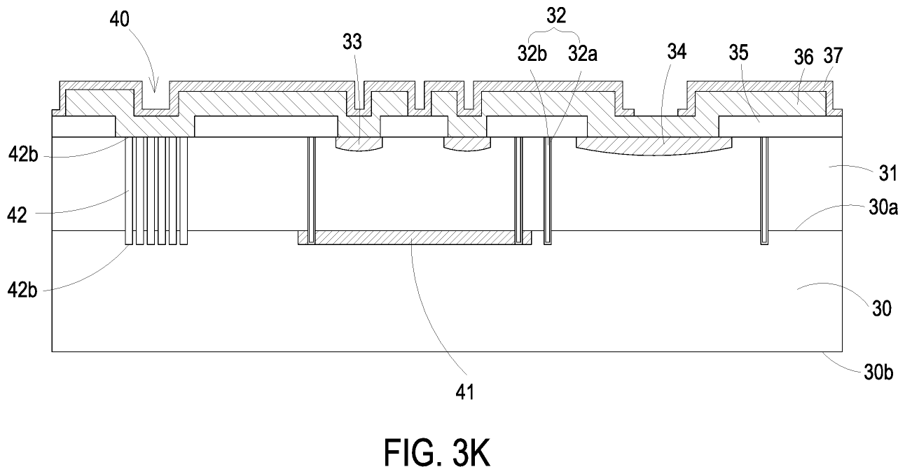

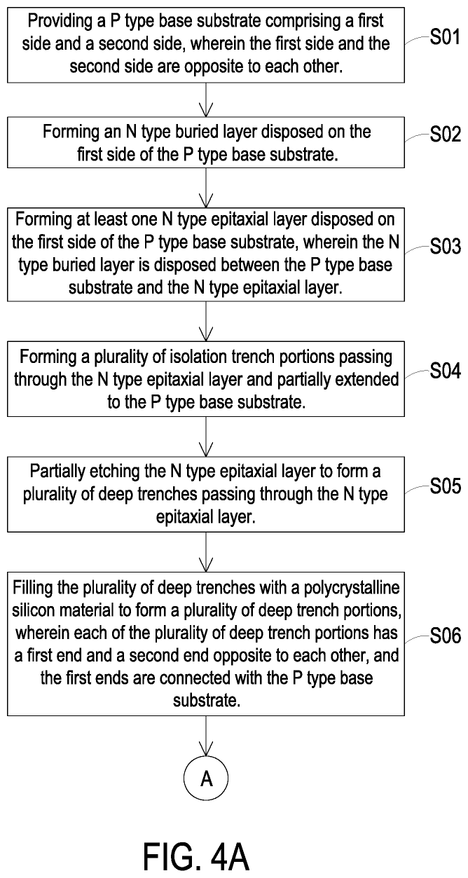

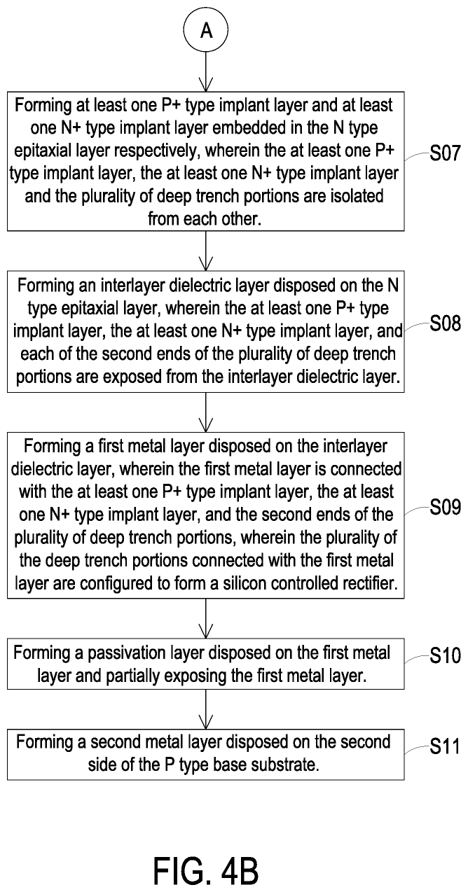

According to the aforementioned transient-voltage-suppression diode structure 3, the present disclosure also discloses a manufacturing method of the transient-voltage-suppression diode structure 3. FIGS. 3A to 3K are cross sectional views illustrating the transient-voltage-suppression diode structure at several manufacturing stages according to the embodiment of the present disclosure. FIGS. 4A and 4B are a flow chart showing a manufacturing method of a transient-voltage-suppression diode structure according to an embodiment of the present disclosure. Please refer to FIGS. 2, 3A to 3K and FIGS. 4A and 4B. Firstly, in the step S01, a P type base substrate 30 is provided. As shown in FIG. 3A, the P type base substrate 30 includes a first side 30a and a second side 30b. The first side 30a and the second side 30b are two opposite sides of the P type base substrate 30 and opposite to each other. Then, in the step S02, an N type buried layer 41 is formed on the P type base substrate 30 by for example but not limited to an implantation and drive-in procedure, as shown in FIG. 3B. In the step S03, at least one N type epitaxial layer 31 is formed on the first side 30a of the P type base substrate 30, so that the N type buried layer 41 is disposed between the first side 30a of the P type base substrate 30 and the N type epitaxial layer 31, as shown in FIG. 3C.

Thereafter, in the step S04, a plurality of isolation trench portions 32 is formed and pass through the N type epitaxial layer 31 and connected with the P type base substrate 30. In the embodiment, the plurality of isolation trench portions 32 are formed by for example but not limited to the dry etching procedure. The N type epitaxial layer 31 and the P type base substrate 30 are partially etched to form a plurality of isolation trenches 32c passing through the N type epitaxial layer 31. Moreover, the plurality of isolation trenches 32 pass through the first side 30a of the P type base substrate 30 and the N type buried layer 41, as shown in FIG. 3D. Thereafter, preferably but not exclusively, a gate oxidation process is performed and then an etch-back process is performed to remove unnecessary oxides, so as to form an oxide layer 32a, which is disposed on the lateral walls and bottoms of the plurality of isolation trenches 32c. Then, the plurality of isolation trenches 32 are filled with a polycrystalline silicon material to form the plurality of isolation trench portions 32, as shown in FIG. 3E. In the embodiment, each of the plurality of isolation trench portions 32 includes the oxide layer 32a and the polycrystalline silicon layer 32b, and the oxide layer 32a covers an outer periphery and a bottom of the polycrystalline silicon layer 32b. However, it is not an essential feature to limit the present disclosure, and not redundantly described herein.

In the step S05, both of the at least one N type epitaxial layer 31 and the P type base substrate 30 are partially etched by the dry etching procedure to form a plurality of deep trenches 42c passing through the N type epitaxial layer 31, as shown in FIG. 3F. In the step S06, the plurality of deep trenches 42c are filled with a polycrystalline silicon material, and an etch-back process is performed to remove unnecessary part of the polycrystalline silicon material, so that a plurality of deep trench portions 42 are formed, as shown in FIG. 3G. Each of the plurality of deep trench portions 42 has a first end 42a and a second end 42b opposite to each other. In the embodiment, the first ends 42a are connected with and extended to the P type base substrate 30. Preferably but not exclusively, the plurality of deep trench portions 42 are formed by a doped polycrystalline silicon layer. By utilizing the dry etching procedure, the plurality of deep trenches 42c are produced easily, and it benefits to avoid the instability of manufacturing process caused by the wet etching. In addition, the plurality of deep trench portions 42 are formed by a doped polycrystalline silicon material, it benefits to avoid the problem of poor metal filling, and the parasitic resistance of, for example the N type epitaxial layer 31 is further reduced, so that the performance of the transient-voltage-suppression diode structure 3 is improved.

In the step S07, the at least one P+ type implant layer 33 and the at least one N+ type implant layer 34 are formed and embedded in the N type epitaxial layer 31. Moreover, the at least one P+ type implant layer 33, the at least one N+ type implant layer 34 and the plurality of deep trench portions 42 are isolated from each other, as shown in FIG. 3H. In other words, the plurality of isolation trench portions 32 are located among the at least one P+ type implant layer 33, the at least one N+ type implant layer 34 and the plurality of deep trench portions 42, so as to isolate the at least one P+ type implant layer 33, the at least one N+ type implant layer 34 and the plurality of deep trench portions 42 from each other. The numbers and arrangement of the at least one P+ type implant layer 33, the at least one N+ type implant layer 34 and the plurality of deep trench portions 42 are adjustable according to the practical requirements. The present disclosure is not limited thereto.

In the step S08, the interlayer dielectric layer 35 is formed on the N type epitaxial layer 31 by for example but not limited to a deposition process and an etching procedure of an interlayer dielectric material. In the embodiment, the at least one P+ type implant layer 33, the at least one N+ type implant layer 34, and the second ends 42b of the plurality of deep trench portions 42 are exposed from the interlayer dielectric layer 35, as shown in FIG. 3I. Thereafter, in the step S09, the first metal layer 36 is formed and disposed on the N type epitaxial layer 31 by for example but not limited to a sputtering process and an etching procedure. In the embodiment, the first metal layer 36 is connected with the at least one P+ type implant layer 33, the at least one N+ type implant layer 34 and the second ends 42b of the plurality of deep trench portions 42. Notably, the plurality of deep trench portions 42 connected with the first metal layer 36 are configured to form a silicon controlled rectifier 40, as shown in FIG. 3J. Moreover, in the step S10, the passivation layer 37 is formed and disposed on the first metal layer 36 and partially exposing the first metal layer 36 to define an output terminal, as shown in FIG. 3K. In the step S11, the second metal layer 38 is further formed on the second side 30b of the P type base substrate 30. The second metal layer 38 is connected to the P type base substrate 30 and is configured to form a ground terminal, as shown in FIG. 2. Certainly, the forming procedures of the passivation layer 37 and the second metal layer 38 are adjustable according to the practical requirement. The present disclosure is not limited thereto, and not be redundantly described herein.

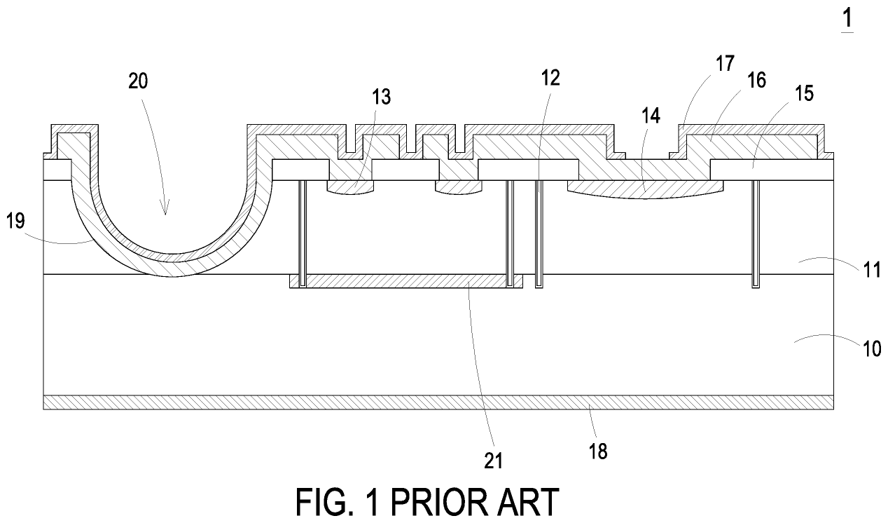

Notably, in the transient-voltage-suppression diode structure 3 of the present disclosure, by utilizing the plurality of deep trench portions 42 to replace the recess 19 (referring to FIG. 1) filled with the metal, the wet etch process is replaced by the dry etch process, and it also benefits to simplify the complexity of process control and is more conducive to controlling the size of the silicon controlled rectifier 40. In addition, the plurality of deep trench portions 42 are formed by a doped polycrystalline silicon material, it benefits to avoid the problem of poor metal filling, and the parasitic resistance of, for example the N type epitaxial layer 31 is further reduced, so that the performance of the transient-voltage-suppression diode structure 3 is improved. Certainly, the formation sequence of the plurality of deep trench portions 42 relative to other structures such as the P+ type implant layer 33 or the N+ type implant layer 34 is adjustable according to the practical requirements. Namely, the dry etching procedure and the polysilicon filling process and the etch-back process used by the plurality of deep trench portions 42 are adjustable according to the practical requirements. The present disclosure is not limited thereto and not redundantly described herein.

In summary, the present disclosure provides a transient-voltage-suppression diode structure and a manufacturing method thereof. The structure of a plurality of deep trench portions formed by for example the dry etching are introduced, it is helpful to avoid the problems of the instability of manufacturing process, the difficulty of controlling the etching rate, and the poor metal filling, which are caused by the wet etching. The performance of the transient-voltage-suppression diode structure is further improved. In addition, the structure of the deep trench portions is utilized to construct a silicon controlled rectifier, it is helpful to control the size thereof and provide the better electrical connection characteristics. While the plurality of deep trench portions are formed by a doped polycrystalline silicon material, the structure of the plurality of deep trench portions is further helpful to reduce the parasitic resistance of, for example the N type epitaxial layer, so as to improve the performance of the transient-voltage-suppression diode structure. In other words, the plurality of polycrystalline deep trench portions formed by for example the dry etching are utilized to construct the silicon controlled rectifier, and it benefits to eliminate the instability of manufacturing process caused by the wet etching and reduce the complexity of manufacturing process. In addition, the structure of silicon controlled rectifier constructed by the plurality of deep trench portions is helpful to control the size thereof and the better electrical connection characteristics of the silicon controlled rectifier are provided. While the plurality of deep trench portions are formed by a doped polycrystalline silicon material, the problem of poor metal filling is avoided, and the parasitic resistance of, for example the N type epitaxial layer is further reduced, so that the performance of the transient-voltage-suppression diode structure is improved.

While the disclosure has been described in terms of what is presently considered to be the most practical and preferred embodiments, it is to be understood that the disclosure needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A transient-voltage-suppression diode structure, comprising:
a P type base substrate comprising a first side and a second side, wherein the first side and the second side are opposite to each other;
an N type epitaxial layer disposed on the first side of the P type base substrate;
at least one P+ type implant layer embedded within the N type epitaxial layer;
at least one N+ type implant layer embedded within the N type epitaxial layer, and isolated from the at least one P+ type implant layer;
a plurality of deep trench portions passing through the N type epitaxial layer, wherein each of the plurality of deep trench portions has a first end and a second end opposite to each other, and the first ends are connected with the P type base substrate;
an interlayer dielectric layer disposed on the N type epitaxial layer, wherein the at least one P+ type implant layer, the at least one N+ type implant layer, and the second ends of the plurality of deep trench portions are exposed from the interlayer dielectric layer; and
a first metal layer disposed on the interlayer dielectric layer and connected with the at least one P+ type implant layer, the at least one N+ type implant layer, and the second ends of the plurality of deep trench portions, wherein the plurality of deep trench portions connected with the first metal layer are configured to form a silicon controlled rectifier.

2. The transient-voltage-suppression diode structure according to claim 1, wherein the plurality of deep trench portions comprise a doped polycrystalline silicon layer.

3. The transient-voltage-suppression diode structure according to claim 1, wherein the plurality of deep trench portions are formed by a dry etching procedure.

4. The transient-voltage-suppression diode structure according to claim 1, further comprising an N type buried layer, wherein the N type buried layer spatially corresponds to the at least one P+ type implant layer and is disposed between the P type base substrate and the N type epitaxial layer.

5. The transient-voltage-suppression diode structure according to claim 1, further comprising a passivation layer, wherein the passivation layer is disposed on the first metal layer, and the first metal layer is partially exposed from the passivation layer.

6. The transient-voltage-suppression diode structure according to claim 1, further comprising a second metal layer disposed on the second side of the P type base substrate.

7. The transient-voltage-suppression diode structure according to claim 1, further comprising a plurality of isolation trench portions passing through the N type epitaxial layer and partially extended to the P type base substrate, wherein the plurality of isolation trench portions are located among the at least one P+ type implant layer, the at least one N+ type implant layer and the plurality of deep trench portions, to isolate the at least one P+ type implant layer, the at least one N+ type implant layer and the plurality of deep trench portions from each other.

8. The transient-voltage-suppression diode structure according to claim 7, wherein each of the plurality of isolation trench portions comprises an oxide layer and a polycrystalline silicon layer, and the oxide layer covers an outer periphery and a bottom of the polycrystalline silicon layer.

9. A manufacturing method of a transient-voltage-suppression diode structure, comprising steps of:
(a) providing a P type base substrate comprising a first side and a second side, wherein the first side and the second side are opposite to each other;
(b) forming at least one N type epitaxial layer disposed on the first side of the P type base substrate;
(c) partially etching the N type epitaxial layer to form a plurality of deep trenches passing through the N type epitaxial layer;
(d) filling the plurality of deep trenches with a polycrystalline silicon material to form a plurality of deep trench portions, wherein each of the plurality of deep trench portions has a first end and a second end opposite to each other, and the first ends are connected with the P type base substrate;
(e) forming at least one P+ type implant layer and at least one N+ type implant layer embedded in the N type epitaxial layer respectively, wherein the at least one P+ type implant layer and the at least one N+ type implant layer are isolated from each other;
(f) forming an interlayer dielectric layer disposed on the N type epitaxial layer, wherein the at least one P+ type implant layer, the at least one N+ type implant layer, and each of the second ends of the plurality of deep trench portions are exposed from the interlayer dielectric layer; and
(g) forming a first metal layer disposed on the interlayer dielectric layer, wherein the first metal layer is connected with the at least one P+ type implant layer, the at least one N+ type implant layer, and the second ends of the plurality of deep trench portions, wherein the plurality of the deep trench portions connected with the first metal layer are configured to form a silicon controlled rectifier.

10. The manufacturing method of the transient-voltage-suppression diode structure according to claim 9, wherein the polycrystalline silicon material is a doped polycrystalline silicon material, and the plurality of deep trench portions comprise a doped polycrystalline silicon layer.

11. The manufacturing method of the transient-voltage-suppression diode structure according to claim 9, wherein the plurality of deep trenches in the step (c) are formed by a dry etching procedure.

12. The manufacturing method of the transient-voltage-suppression diode structure according to claim 9, wherein the step (b) further comprises a step of:
(b0) forming an N type buried layer, wherein the N type buried layer is disposed between the P type base substrate and the N type epitaxial layer, and spatially corresponds to the at least one P+ type implant layer.

13. The manufacturing method of the transient-voltage-suppression diode structure according to claim 9, further comprising a step of:
(h1) forming a passivation layer disposed on the first metal layer and partially exposing the first metal layer.

14. The manufacturing method of the transient-voltage-suppression diode structure according to claim 13, further comprising a step of:
(h2) forming a second metal layer disposed on the second side of the P type base substrate.

15. The manufacturing method of the transient-voltage-suppression diode structure according to claim 9, wherein the step (c) further comprises a step of:
(c0) forming a plurality of isolation trench portions passing through the N type epitaxial layer and partially extended to the P type base substrate, wherein the plurality of isolation trench portions are located among the at least one P+ type implant layer, the at least one N+ type implant layer and the plurality of deep trench portions, to isolate the at least one P+ type implant layer, the at least one N+ type implant layer and the plurality of deep trench portions from each other.

16. The manufacturing method of the transient-voltage-suppression diode structure according to claim 15, wherein the step (c0) further comprises steps of:
(c01) partially etching the at least one N type epitaxial layer and the P type base substrate to form a plurality of isolation trenches passing through the N type epitaxial layer;
(c02) forming an oxide layer disposed on lateral walls and bottoms of the plurality of isolation trenches; and
(c03) filling the plurality of isolation trenches with a polycrystalline silicon material to form the plurality of isolation trench portions, wherein the plurality of isolation trench portions pass through the N type epitaxial layer and are partially extended to the P type base substrate, wherein the plurality of isolation trench portions are located among the at least one P+ type implant layer, the at least one N+ type implant layer and the plurality of deep trench portions, to isolate the at least one P+ type implant layer, the at least one N+ type implant layer and the plurality of deep trench portions from each other.
